(19) United States
(12) Patent Application Publication
(10) Pub. No.: US 2019/0056353 A1
(43) Pub. Date: Feb. 21, 2019

(54) HYBRID METHOD TO SYNTHESIZE VOLTAGE WAVEFORMS WITH NON-HARMONIC PROFILES

(71) Applicants: Wichita State University, Wichita, KS (US); Gordon A. Anderson Custom Engineering, Benton City, WA (US)

(72) Inventors: Alexandre A. Shvartsburg, Wichita, KS (US); Gordon A. Anderson, Benton City, WA (US)

(73) Assignees: Wichita State University, Wichita, KS (US); Gordon A. Anderson Custom Engineering, Benton City, WA (US)

(21) Appl. No.: 16/078,847

(22) PCT Filed: Apr. 12, 2017
(86) PCT No.: PCT/US17/27179

§ 371 Date: Aug. 22, 2018

Related U.S. Application Data
(60) Provisional application No. 62/341,338, filed on May 25, 2016.

(51) Int. Cl. G01N 27/62; H01J 49/00; G01R 23/165; G01R 23/20

(52) U.S. Cl. CPC G01N 27/624; H01J 49/004; H01J 49/42; G01R 23/20; G01R 23/165

(57) ABSTRACT

Method and apparatus for generating asymmetric high-voltage waveforms with near-rectangular profiles. The method comprises producing selected low-frequency components of the Fourier series for a rectangular waveform explicitly and adding them to the amplified residual of lower-amplitude near-rectangular waveform upon filtering out certain frequencies.

### CROSS-REFERENCE TO RELATED APPLICATIONS

This patent application claims priority to U.S. Provisional Patent Application Ser. No. 62/341,338, filed May 25, 2016, and entitled Hybrid Method to Synthesize Voltage Waveforms with Non-Harmonic profiles, which is hereby incorporated by reference in its entirety into the present application.

### BACKGROUND OF THE INVENTION

Alternating voltages are broadly used in most areas of industry, including power generation and transmission, manufacturing, electrical appliances, and scientific instrumentation. The common goal of delivering the electrical power to a load such as a motor or Ohmic heater is readily achieved using harmonic (sinusoidal) waveforms readily produced by electrical generators, and most ac systems involve those waveforms. Many other application require a dc voltage, and harmonic waveforms are easily converted into them by techniques well-known in the electrical arts.

However, some applications require or benefit from ac waveforms with non-harmonic profiles, most commonly rectangular comprising two alternating voltage levels of opposite polarities. Those waveforms are easy to produce at low voltage and/or frequency by direct mechanisms such as digital-to-analog converters and waveform generators, but not at high voltage and frequency where rapid switching between substantially different voltages involves huge electrical currents. The brute-force key switching between two voltage outputs at the desired levels requires enormous electrical power and is unsafe because of essentially unrestricted current at high voltages.

One important and rapidly growing area of application for high-voltage rectangular waveforms is ion mobility spectrometry (IMS) analyses employing dynamic electric fields, including but not limited to nonlinear IMS. The capability for speedy yet extensive chemical characterization of complex samples is central to modern biomedical and environmental research. This process normally involves mass-spectrometry (MS) that features exceptional sensitivity, specificity, dynamic range, and speed. Even with those capabilities, most real-world analyses require substantial prior separations to simplify mixtures delivered to the MS step. Those separations have traditionally been performed in liquids or on solid/liquid interfaces using capillary electrophoresis (CE) and/or liquid chromatography (LC), often with multiple consecutive stages for higher peak capacity. Such condensed-phase methods are inevitably slow because of sluggish molecular motion in liquids and insufficiently specific for many common compound classes such as lipid isomers and peptides or proteins with variant localization of post-translational modifications (PTMs).

Over the last decade, those pre-ionization separations have been increasingly supplemented or replaced by IMS, where ions driven through gases by an electric field are sorted by some transport property. These methods are faster than LC or CE by several orders of magnitude (in proportion to the molecular speeds in gases) and allow impressive separations well within 1 s. However, linear IMS methods employing fields of moderate intensity E (such as the drift-tube and traveling-wave IMS) are based on the absolute ion mobilities (K) that are proportional to inverse orientationally-averaged collision cross sections and thus tightly correlated with the ion mass. This greatly limits the orthogonality to MS and thus the utility of IMS/MS combination.

The mobility of any ion in a gas above certain threshold in terms of E/N (where N is the gas number density) deviates from its zero-field limit K₀, increasing or decreasing at high E values. This nonlinearity is leveraged in the newer approach of differential or field asymmetric waveform IMS (FAIMS), where ions are stratified by the derivative of K(E) function. That function can be expanded in a power series comprising even-power terms:

K(E)=K₀[1+a(E|N)²+b(E|N)⁴+c(E|N)⁶ . . . ] (1)

where a, b, and c are the coefficients with appropriate terms.

In practice, ions are injected into a gap between two electrodes carrying a periodic asymmetric waveform with superposed small compensation voltage (CV). While pulled through the gap by gas flow (or potentially weak field established via longitudinal electrode segmentation), ions are dispersed perpendicularly to it with each species equilibrated at a particular CV determined by the form of K(E). Scanning CV permits selecting different species for transmission to a down-stream ion detector (commonly an MS system), producing a spectrum of ions entering the gap. While this FAIMS separation is not fully orthogonal to MS, it is more orthogonal than linear IMS by ˜3-4 times for the major biomolecular classes such as lipids and peptides (Shvartsburg et al, J. Am. Soc Mass Spectrom. 22, 1146, 2011).

As with any separation, the key performance metric of FAIMS is the resolving power (R) that controls the resolution in targeted analyses. This metric depends on the gap shape, maximizing for planar gaps with spatially homogeneous field and dropping for more curved (cylindrical or spherical) gaps as the increasingly inhomogeneous field augments the ion focusing and thus the transmission efficiency (sensitivity) at the cost of lower resolution (Shvartsburg et al., Anal. Chem. 78, 3706, 2006). This trade-off between resolution and sensitivity is typical for filtering MS and IMS techniques, such as the magnetic sector MS and especially quadrupole MS that resembles FAIMS in some aspects.

A major factor that governs the resolution for any gap shape is the waveform profile. The theoretical optimum is rectangular with the ratio of amplitudes in two polarities equal to two or ranging from ˜1.3 to ˜2.6 when eq (1) is truncated at the quadratic or 4^{th}-power terms, respectively (Shvartsburg and Smith, J. Am. Soc. Mass Spectrom. 19, 1286, 2008).

Most FAIMS systems, including custom research and commercial products, employ the bisinusoidal waveform generated by adding two harmonics—commonly with the ratio of 2:1 for frequencies and 1:2 for amplitudes (Guevremont, J. Chromatogr. A 1058, 3, 2004). While relatively easy to implement, that profile delivers ˜40-50% of the resolving power possible with rectangular waveforms. (The number slightly depends on the coefficients in eq (1), equaling 4/9 if the terms beyond quadratic are ignored). Some systems utilize the clipped-sinusoidal waveforms derived by capping the voltage of a single harmonic (Buryakov, J. Chromatogr, B 800, 75, 2004) or other profiles (Shvartsburg et al., Anal. Chem. 81, 6489, 2009) intended to crudely approximate the rectangular one at modest engineering cost, but those approaches suffer from a similar performance penalty. Near-rectangular waveforms have been evaluated in several research prototypes using switches (Papanastasiou et al., J. Phys. Chem. A 112, 3638, 2008), and the gains relative to the harmonic-based profiles were in line with theory. Nonetheless, the low voltage and/or frequency needed to create a rectangular waveform by that approach within reasonable engineering constraints have resulted in poor absolute resolution and/or sensitivity.

Separation parameters are also useful to identify unknowns by matching with the data for known species, in particular as a part of the accurate mass and time (AMT) tag approach to omic analyses (Zimmer et al., Mass Spectrom. Rev. 25, 450, 2006). The key criterion here is the measurement accuracy that also benefits from higher resolving power and therefore would be improved by transition to rectangular waveforms.

Nonlinear IMS methods further comprise the proposed higher-order differential (HOD) IMS that would sort ions by the higher K(E) derivatives employing an asymmetric waveform with three or more voltage levels (Shvartsburg et al., J. Phys. Chem. A 110, 2663, 2006). This separation ought to be largely orthogonal to FAIMS and yet more orthogonal to linear IMS and MS than FAIMS is, enabling novel analyses by itself and in multidimensional methods in conjunction with FAIMS and/or linear IMS. Rectangular profiles appear even more crucial to HODIMS than to FAIMS, and the lack of a practical method to generate high-voltage rectangular waveforms has been the key obstacle to demonstration of HODIMS so far.

A hallmark of FAIMS or HODIMS filters is the balance between resolution, sensitivity, and speed that can be tilted to meet the specific priorities by varying the gap geometry (width, length, and curvature) and/or the ion residence time (t) that scales inversely to the gas flow rate (in flow-driven devices) or longitudinal field (in field-driven devices). For instance, a shorter t decreases the resolution, but improves sensitivity and speed. Hence the gain of resolving power delivered by a rectangular waveform can be fully or partially exchanged for gains of sensitivity and/or speed. As in planar-gap FAIMS or HODIMS devices the value of R scales as t^{1/2} (Shvartsburg and Smith, J. Am. Soc. Mass Spectrom, 18, 1672, 2007), increasing the resolving power by (for example) 2.25 times could be traded for a fivefold acceleration of analysis. That would be particularly helpful in the LC/FAIMS/MS arrangement, where “nested” separations require fitting the FAIMS step within the elution of LC features.

The resolving power of FAIMS generally scales as the cube of waveform amplitude (dispersion voltage, DV). Hence switching to rectangular waveforms would allow reducing the DV at fixed instrumental resolution by ˜28%, which potentially simplifies the system engineering, decreases the risk of arc discharge, expands the range of possible buffer gas compositions, and improves the electrical safety.

The unique characteristics of an ion species pertinent to the differential IMS is the alpha-function—the relative change of K depending on the electric field:

a(E)=K(E)/K₀−1 (2)

This function convoluted with the waveform profile defines the CV(DV) dependence and hence can be extracted by deconvolution of that dependence measured by FAIMS, allowing a direct comparison of data obtained using different devices. That deconvolution would be more straightforward and robust with rectangular waveforms, improving the accuracy of resulting a(E) curves and thus the specificity of identifications based on them. More accurate a(E) data would also allow tighter comparisons with theoretical curves derived from molecular dynamics, improving our understanding of differential IMS fundamentals.

Another proposed nonlinear IMS method is IMS with the alignment of dipole direction (IMS-ADD), where a strong alternating electric field turns macromolecular ions with sufficiently large dipole moments into flipping pendular states to permit the measurement of directional ion-molecule collision cross sections and separations based on them (Shvartsburg et al., U.S. Pat. No. 7,170,053). Those cross sections in the direction perpendicular or parallel to the permanent dipole ought to provide more specific structural information about the ions than the orientationally-averaged quantities determined by linear IMS. Whereas IMS-ADD can in principle be implemented using harmonic waveforms, the rectangular waveforms with single voltage level will improve the resolution and specificity of approach and drastically simplify the data interpretation.

Therefore, there is a demand for effective methods to safely generate near-rectangular symmetric or asymmetric waveforms with high voltages and frequencies close to those of harmonic-based profiles, specifically ˜4-5 kV and ˜1 MHz for “full-size” nonlinear IMS devices with the gap widths of ˜2 mm operating at ambient gas pressure. In principle, any waveform can be represented as a Fourier series and thus synthesized by superposing the constituent harmonics. However, constructing a rectangular profile with sufficient fidelity by that approach requires generating and precisely phase-locking and adding tens of harmonics (some at very high frequency), which is impractical from the electrical engineering perspective.

### SUMMARY OF THE INVENTION

Accordingly, the primary object of the invention is to provide an effective capability to safely generate high-voltage waveforms of rectangular and other non-harmonic profiles for a wide range of applications. A subsidiary object of the invention is to broadly augment the resolving power and thus the resolution of differential IMS methods of all orders for separation and identification of gas-phase ions by providing a novel approach to establish near-rectangular high-voltage waveforms within the practical constraints of generator power and weight, and without endangering the operator. Another object is to enable a broad gain of the sensitivity and speed of differential IMS at a given resolution by trading in the advantage in separation efficiency. Yet another object is to provide a similar separation performance at a lower maximum voltage and electric field strength, simplifying the selected aspects of overall system engineering, increasing the flexibility of buffer gas selection, and improving the electrical safety. A further object is to raise the accuracy of K(E) and alpha-function curves extracted from raw FAIMS data, improving the specificity of ion identifications and facilitating the development of theory and computational tools for the modeling of differential IMS separations. A still other object of the invention is to improve the resolving power and specificity of IMS-ADD methods.

These and other objects of the invention are achieved by the disclosed novel method and apparatus for the generation of asymmetric high-voltage waveforms with near-rectangular profiles. Its fundamental novel feature is a hybrid approach that involves producing selected low-frequency components of the Fourier series for a rectangular waveform explicitly and adding them to the amplified residual of lower-amplitude near-rectangular waveform upon filtering out the frequencies of above components. In broad terms, the approach comprises the steps of (a) producing harmonic waveforms, (b) producing rectangular waveforms, (c) filtering any waveform to remove all harmonics below the desired low-frequency cut-off, (d) linearly amplifying the waveform of any profile, and (e) superposing the waveforms of any profile.

This approach is motivated by two juxtapositions: (i) explicitly generating and adding several leading low-frequency harmonics of the needed Fourier series (as is already practiced in FAIMS for two harmonics) is straightforward, yet generating enough to truncate the series with a negligible impact on the ensuing waveform profile is made impractical by the challenges of both overall system complexity and producing individual harmonics at very high frequency, and (ii) explicitly generating a near-rectangular waveform at low voltage is straightforward (and has been used in the FAIMS context), yet same at high voltage is impractical for reasons of power requirements, heat release, and electrical safety. Consideration of these factors and the realization that the superposition of the remainder of Fourier series for a rectangular waveform rapidly drops in amplitude with the increasing number of expressly included terms have guided the inventors to the present approach, where a limited number of low-frequency high-voltage terms are generated explicitly and the rest are delivered cumulatively as a rectangular waveform at moderate voltage (less the terms for pre-generated frequencies).

### BRIEF DESCRIPTION OF THE DRAWINGS

FIG. 1a is a graph showing prior art exemplary dependences of ion mobility on the electric field intensity.

FIG. 1b depicts a prior art scheme of FAIMS device and ion trajectories within its analytical gap during separation.

FIG. 2 illustrates prior art ideal rectangular asymmetric waveforms for FAIMS and 1^{st}-order HOD IMS separations.

FIG. 3 shows the expansion of rectangular FAIMS waveform with 2:1 aspect ratio into a Fourier series.

FIG. 4 illustrates the concept of present invention, where the four leading harmonics are generated explicitly and added to the rectangular waveforms treated using a high-pass filter and subsequently amplified.

### DETAILED DESCRIPTION

While the present disclosure is exemplified by specific embodiments, the invention is not limited thereto and variations in form and detail may be made without departing from the spirit and scope of the invention. All such modifications as would be envisioned by those of skill in the art are hereby incorporated.

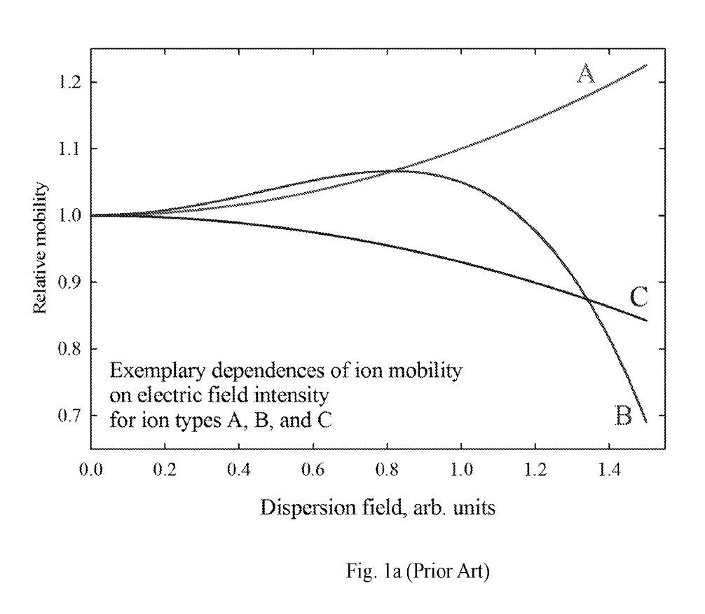

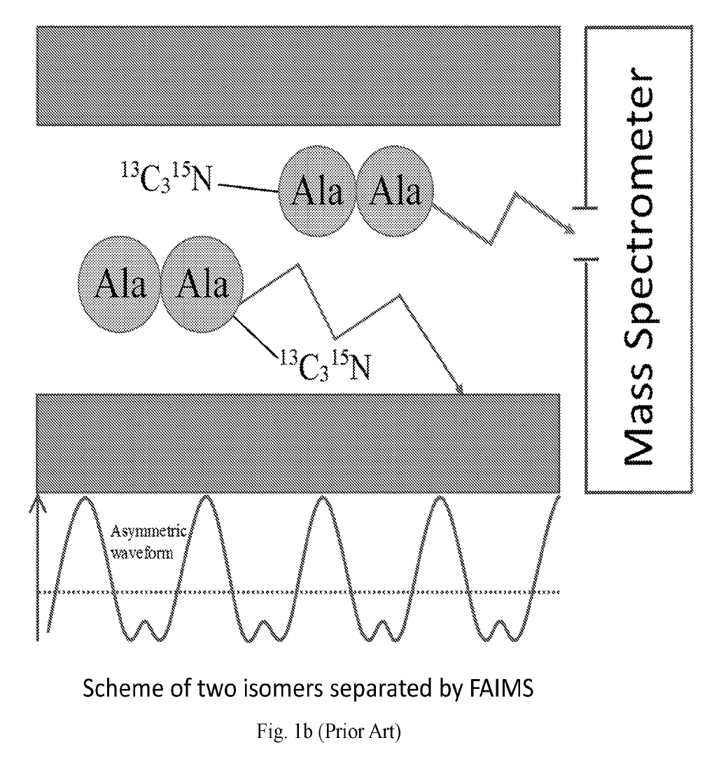

The production and use of non-harmonic waveforms generated according to the instant invention is illustrated below with respect to the separation and identification of ions by nonlinear IMS methods. In particular, differential ion mobility spectrometry exploits the dependence of mobility (K) on electric field intensity (E), elicited directly using an asymmetric rf waveform loaded on a pair of electrodes [FIG. 1a]. This includes the 1^{st}-order differential IMS or field asymmetric waveform IMS (FAIMS) based on the difference between K at two E values, i.e., the average 1^{st} derivative of K(E) function between those values. The invention also applies to higher-order differential (HOD) IMS methods based on the second and higher K(E) derivatives, determined by the coefficients b, c, etc. of eq (1) without the influence of coefficient a with the quadratic term.

Ions introduced into a gap of any shape between those electrodes are dispersed orthogonally to it and, on top of oscillations with the waveform period, experience net drift to one of the electrodes. This motion for a particular species is offset by equal and opposite drift caused by dc compensation voltage (CV) co-loaded with the waveform, while other species still impinge on the electrodes and are neutralized [FIG. 1b]. Scanning the CV allows different ions to pass the gap and be registered by a detector or further processed by another stage, revealing the spectrum of species present. Alternatively, a fixed CV allows pulling a given species out of a complex mixture for further processing.

The stage following differential IMS is commonly a mass spectrometer, but may be a differential IMS stage of other separation order or otherwise distinct selectivity, a linear IMS stage, a laser spectrometer such as a photoelectron or photodissociation spectrometer, or a combination of two or more of said stages. Said mass spectrometer may be of the ion trap, Orbitrap, Fourier transform ion cyclotron resonance (FTICR), transmission quadrupole, magnetic sector, or other type, or a combination thereof for tandem MS and MS' analyses, without limitation. Said linear IMS stage may be of the drift tube, traveling wave (TWIMS), funnel trap (TIMS), differential mobility analyzer (DMA), cyclotron IMS, or other type, or a combination thereof for tandem IMS and MS' analyses, without limitation.

Simulations and experiments have shown that the optimum waveforms for FAIMS and HODIMS of all orders are “rectangular”, consisting of level segments joined by vertical rises or falls. The number of needed segments equals the order of differential separation plus one, e.g., two for FAIMS, three for 1st-order HODIMS, and four for the 2^{nd}-order HODIMS.

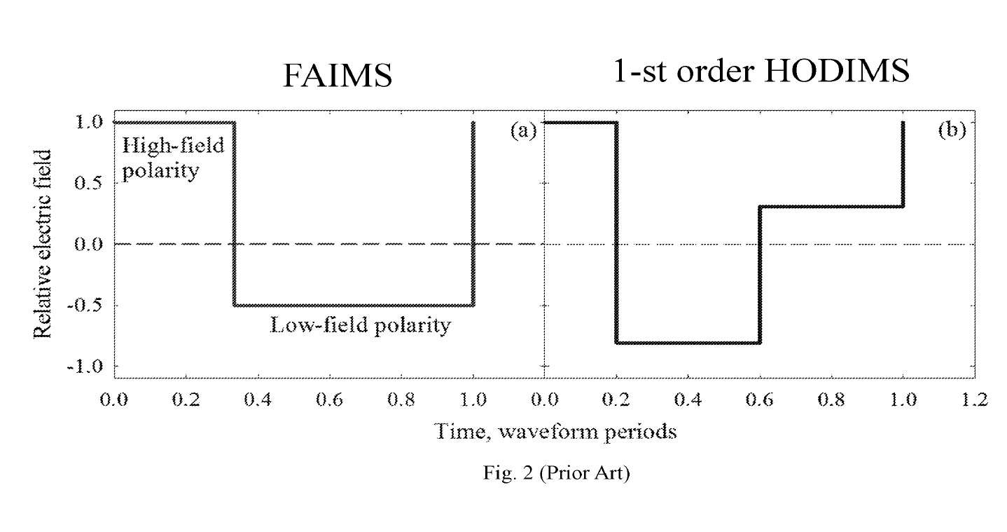

For FAIMS, the calculated ratio of voltages in opposite polarities (the aspect ratio, f) for maximum CV is exactly two if eq (1) is truncated at the a(E/N)² term (FIG. 2) and ranges from 1.24 to ˜2.6 if truncated at the b(E/N)⁴ term, depending on the b/a ratio and maximum E/N (Shvartsburg. Differential Ion Mobility Spectrometry. Nonlinear Ion Transport and Fundamentals of FAIMS. CRC Press, Boca Raton, Fla., 2008). Consideration of the c(E/N)⁶ and further terms of eq (1) may introduce further corrections to the optimum f value. While rigorously optimizing the profile requires a different f for each targeted ion pair, the outcome within 10% of optimum is achievable using just two profiles—one (with higher f) for ions of types A and C where the mobility consistently increases or decreases with growing E/N and another (with lower f) for ions of type B where the mobility first increases to a certain maximum and then decreases.

The aspect ratio also affects the mean field heating and thus the high-field anisotropic diffusion of ions during the waveform cycle, which controls the peak width, w (customarily defined at the half maximum). Hence the FAIMS resolving power, which equals (CV)/w, depends on f through both CV and w and maximizes at a somewhat different f than the CV itself. The optimum f depends on the magnitude of E/N that sets the extent of field heating and, with eq (1) truncated at the quadratic term, varies from 2 to 4 in the low- and high-field limits, respectively. Combination of this diffusion factor with the contribution of 4^{th}-power and higher terms of eq (1) may modify the optimum f still further.

The waveform profiles for HODIMS of all orders have thus far been optimized with the eq (1) limited to the appropriate leading term and without accounting for the diffusion factor. The result for 1^{st}-order HODIMS comprises segments with the relative voltages of 1, −0.809, and 0.309 and durations of ⅕, ⅖, and ⅖ of the period, respectively (FIG. 2). The 2^{nd}-order HODIMS would utilize the voltages of 1; −0.223, 0.623, and −0.901 and durations of 1/7, 2/7, 2/7, and 2/7, respectively. The profiles for yet higher orders can be constructed following the systematic procedure laid out by Shvartsburg et al. (J. Phys. Chem. A 110, 2663, 2006). Consideration of the further terms in eq (1) and high-field diffusion would somewhat modify the above values.

The waveform profiles for IMS-ADD would be symmetric rectangular, with the maximum voltage allowed by electrical breakdown and electrical engineering limitations.

These profiles exemplify the options performing well in experiment or simulations in specific circumstances for common analyte classes, but do not limit the scope of invention. Other adjustments to the rectangular waveforms for FAIMS and HODIMS may be desired to reduce the amplitude of ion oscillations during the waveform cycle, to simplify the electrical engineering tasks, and for other practical reasons. The rise and fall times also cannot be null, but should best be within a few percent of the period. Such adjustments are fully envisioned in the art, and all profiles substantially rectangular in full or in part fall within the scope and are deemed “rectangular” for the purpose of this disclosure.

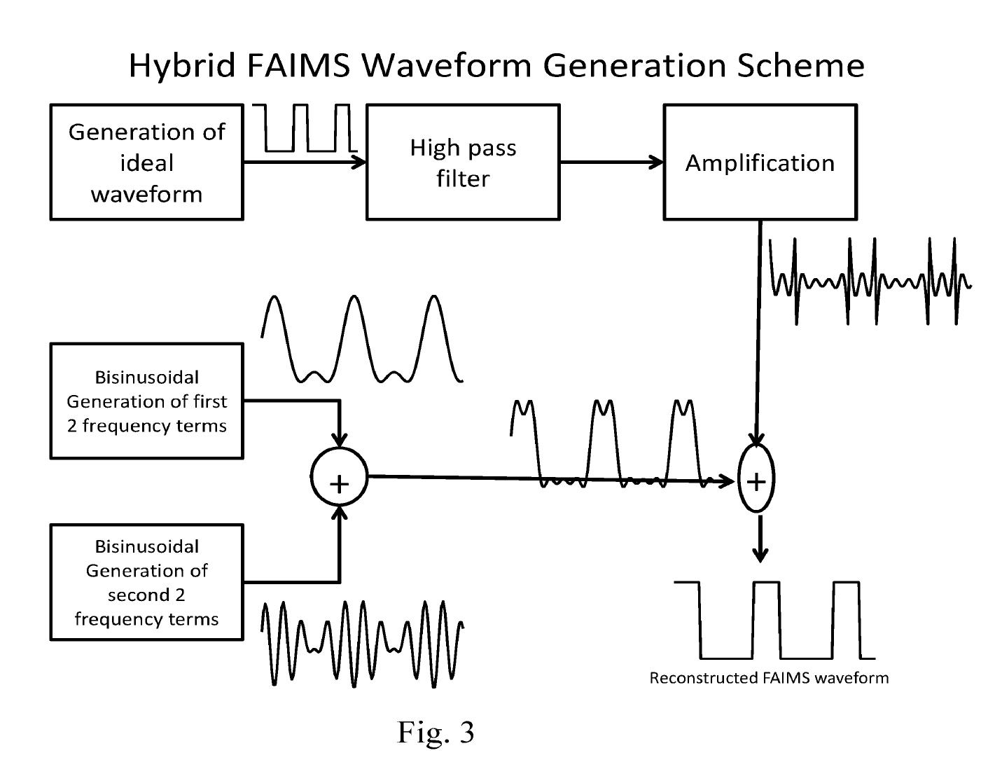

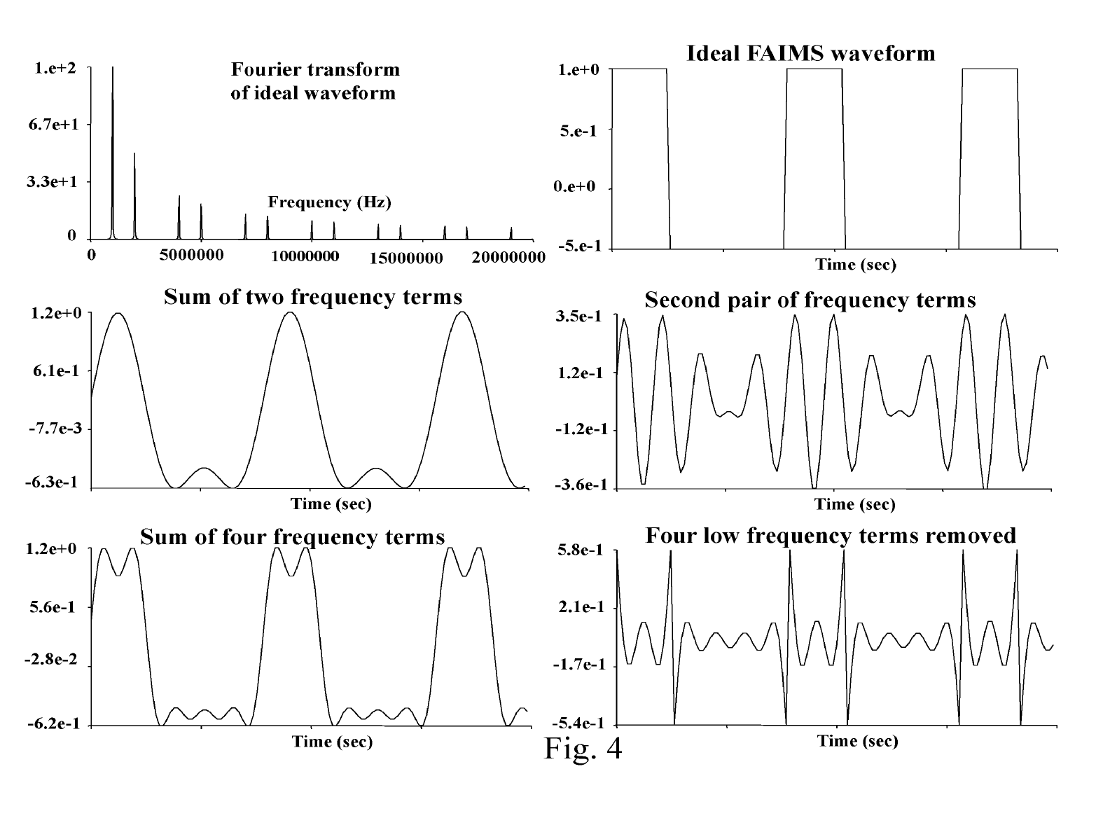

According to the invention, the rectangular waveform is blended up by an approach combining the elements of methods to generate harmonic and rectangular waveforms, while sidestepping their deficiencies. The desired profile is decomposed into a Fourier series using well-known mathematical formalisms such as the fast Fourier transform (FFT) and associated software (FIG. 3). A pre-determined finite number n (for example, without limitation, a number of 1-200) of leading harmonics of lowest frequency and highest amplitude is produced directly with requisite phases, employing means known in the art (such as resonating circuits that are tunable within certain ranges) to deliver the sinusoidal waveforms of targeted frequency and amplitude (FIG. 4). Separately, a rectangular waveform of much lower amplitude is produced by key switching (logic levels) and filtered through a high-pass frequency filter to eliminate the low-frequency harmonics up to and including the frequency of the n-th harmonic. The output is amplified to the desired level (for example, using a linear broadband amplifier) and then summed with the individually generated harmonics (FIG. 4).

The choice of n is governed by the balance between simplicity of electronic implementation (favoring lower n) and advantage of the present hybrid approach (favoring higher n). Of particular interest with respect to FAIMS is n=4, where all higher harmonics encompassed within the rectangular profile have an amplitude under 14% of the dispersion voltage: e.g., just ˜770 V for the final waveform with DV=5.5 kV−the maximum reported in the art (Shvartsburg et al., Anal. Chem. 82, 7649, 2010). The corresponding fraction would increase to 24% with the minimum n=2 and decrease to 9% with the next n=6. While these embodiments are described by way of example, the invention is not limited to any particular n and another number may be preferred depending on the order of differential IMS separation, aspect ratio of desired rectangular waveform, performance requirements, constraints of generator size, weight, and electrical power, and the availability and cost of hardware options.

Whereas the utility of present invention is illustrated by application to nonlinear IMS, high-voltage rectangular waveforms are desired in other mass spectrometric and analytical systems and broader electrical engineering contexts. This invention is expressly not limited to its use in a specific analytical device, but extends its scope to all systems employing the presently disclosed hybrid approach to rectangular waveform synthesis.

Further, while the enablement and benefits of present invention are illustrated for rectangular waveforms, the presently disclosed hybrid synthesis method equally applies to other non-harmonic profiles (such as triangular and trapezoidal) that may be desired in other applications. The extension of essentially the same method to other profiles is within the scope of this invention.

Having thus described the preferred embodiment of the invention, what is claimed as new and desired to be protected by Letters Patent includes the following:

1. A method to synthesize a desired voltage waveform of other than a harmonic profile, the method comprising the steps of:
i. generating an initial voltage waveform of said profile at a lower amplitude than a desired final amplitude;
ii. substantially depleting a finite number of lower-frequency components of a Fourier series of said initial waveform in (i) to yield a depleted waveform;
iii. amplifying the depleted waveform produced in (ii) to an amplitude wherein non-depleted components have magnitudes approximately equal to the amplitude of the desired voltage waveform;
iv. generating said finite number of lower-frequency components as individual harmonics with amplitudes approximately matching those in the desired voltage waveform; and
v. superposing all the waveforms obtained in (iii) and (iv).

2. The method of claim 1, wherein said lower-frequency components in (ii) are consecutive lower-order terms of the Fourier series.

3. The method of claim 1, wherein said lower-frequency components are depleted in (ii) using a high-frequency pass filter.

4. The method of claim 3, wherein said filter has an adjustable low-frequency cutoff or slope.

5. The method of claim 1, wherein said lower-frequency components are generated in (iv) using individual resonating circuits.

6. The method of claim 5, wherein said circuits have tunable resonance frequencies.

7. The method of claim 1, wherein said finite number of lower-frequency components depleted in (ii) and generated in (iv) is four.

8. The method of claim 1, wherein said finite number of lower-frequency components depleted in (ii) and generated in (iv) is selected from the group of two, six, and eight.

9. The method of claim 1, wherein the desired voltage waveform comprises two substantially flat segments with equal voltage levels of opposite polarity.

10. The method of claim 9, wherein the desired voltage waveform is employed to implement ion mobility spectrometry with the alignment of dipole direction (IMS-ADD).

11. The method of claim 1, wherein said desired voltage waveform comprises two substantially flat segments with unequal voltage levels of opposite polarity.

12. The method of claim 11, wherein the desired voltage waveform is employed to implement differential ion mobility spectrometry or field asymmetric waveform ion mobility spectrometry (FAIMS) analyses.

13. The method of claim 1, wherein said desired voltage waveform comprises at least three substantially flat segments with unequal voltage levels.

14. The method of claim 13, wherein the desired voltage waveform is employed to implement higher-order differential ion mobility spectrometry (HODIMS) analyses.

15. The method of claim 1, wherein (v) is effected in at least two separate superposition sub-steps.

16. The method of claim 15, wherein the first sub-step is adding all said individual waveforms generated in (iv) and the second sub-step is superposing the result on the amplified depleted waveform formed in (iii).

17. The method of claim 1, wherein said desired voltage waveform of other than harmonic profile is an asymmetric high-voltage waveform with a near-rectangular profile, wherein:
said initial voltage waveform in (i) is a rectangular waveform;
said lower-frequency components are depleted by filtering the rectangular waveform to remove harmonics below a desired low-frequency cut-off to produce a filtered rectangular waveform that is said depleted waveform in (ii);
said depleted waveform is amplified in (iii) by linearly amplifying the filtered rectangular waveform to produce an amplified rectangular waveform; and
said superposing in (v) comprises summing the amplified rectangular waveform with the individual harmonic waveforms generated in (iv).

18. The method of claim 17, wherein the asymmetric high-voltage waveform is employed to implement ion mobility spectrometry with the alignment of dipole direction (IMS-ADD).

19. The method of claim 17, wherein the asymmetric high-voltage waveform is employed to implement differential ion mobility spectrometry or field asymmetric waveform ion mobility spectrometry (FAIMS) analyses.

20. The method of claim 17, wherein said lower-frequency components are filtered with a high-frequency pass filter.
